(19) United States
(12) Patent Application Publication
(10) Pub. No.: US 2012/0318361 A1
(43) Pub. Date: Dec. 20, 2012

(54) MANUFACTURING THIN FILMS WITH CHALCOGEN SPECIES WITH INDEPENDENT CONTROL OVER DOPING AND BANDGAPS

(75) Inventors: Glenn Teeter, Lakewood, CO (US); Hui Du, Golden, CO (US); Matthew Young, Lakewood, CO (US); Pete Erslev, Golden, CO (US)

(73) Assignee: ALLIANCE FOR SUSTAINABLE ENERGY, LLC, Golden, CO (US)

(21) Appl. No.: 13/528,096

(22) Filed: Jun. 20, 2012

Related U.S. Application Data
(60) Provisional application No. 61/499,030, filed on Jun. 20, 2011.

(51) Int. Cl. H01L 31/0296; H01L 31/18

(52) U.S. Cl. 136/264; 438/95; 136/265; 257/E31.015

(57) ABSTRACT

A method for synthesizing a thin film of CZTS such as for use as an absorber in a photovoltaic device. The method includes providing a substrate in a chamber, and, then, depositing a film of CZTS material on the substrate, the CZTS material comprising copper, zinc, tin, and at least on chalcogen species. The depositing includes tuning an optical bandgap of the film with heterovalent alloying. The depositing is performed at low temperatures with the substrate provided in the chamber free of direct/active heating. For example, the substrate may be maintained at a temperature below about 150° C. during the depositing of the film. The heterovalent alloying involves controlling deposition rates for the copper and the zinc to define a copper to zinc ratio set the optical bandgap such as a value between about 1.0 eV and about 2.75 eV.

### CROSS-REFERENCE TO RELATED APPLICATIONS

This application claims the benefit of U.S. Provisional Application No. 61/499,030 filed Jun. 20, 2011, which is incorporated herein by reference in its entirety

### CONTRACTUAL ORIGIN

The United States Government has rights in this invention under Contract No. DE-AC36-08G028308 between the United States Department of Energy and the Alliance for Sustainable Energy, LLC, the Manager and Operator of the National Renewable Energy Laboratory.

### BACKGROUND

Thin-film photovoltaic (PV) devices may be used to create solar cells, detectors, electronic devices, telecommunication devices, charge-coupled imaging devices (CCDs), computers, and even biological or medical devices (together considered “thin-film compound semiconducting materials”). With regard to renewable energy, solar cells are devices that have characteristics that enable them to convert the energy of sunlight into electric energy. The aim of research often is to achieve solar cell designs with the lowest cost per watt generated by the solar cell, and, concurrently, the designs should provide solar cells that are suitable for inexpensive commercial production.

The potential market for thin-film photovoltaic (PV) devices is enormous and is expected to continue to grow in the coming years. Recently, a goal was set to globally deploy one terawatt of continuous PV-based power, and achieving this goal will require an industry that can supply on the order of 300 to 400 GWp (gigawatt peak) of PV modules each year. Additionally, in the United States, goals concerning costs have been set that include a module-level cost goal for utility-scale PV installations of 0.5 $/Wp, which would make unsubsidized PV competitive with conventional power sources. At this cost level and at a deployment level in the hundreds of GWp per year, PV module sales globally may be in excess of $50 billion (in U.S. dollars) per year. As will be appreciated, any technology that can better enable the PV industry, such as by increasing efficiencies, reducing material costs, lowering manufacturing expenses, and the like, has a large potential for growth and revenue generation.

A conventional thin-film solar cell is composed of a stacking of thin layers (e.g., 1 to 2 μM thick layers) on a substrate, and the thin layers form one or more junctions with differing band gaps that absorb light and convert it into electricity. Presently, most compound semiconductor thin-film solar cells are fabricated with an absorber or absorber layer formed of cadmium telluride (CdTe) or copper indium gallium diselenide (CIGS), both of which have high optical absorption coefficients and have versatile optical and electrical characteristics. The thin-film PV industry based on CdTe and CIGS recently had sales approaching $2 billion (in U.S. dollars) per year, with sales continuing to rapidly grow.

Unfortunately, there are concerns in the PV industry that reliance on CdTe and CIGS thin-film devices may not be sustainable. For example, many have expressed concern that the costs of raw materials such as tellurium and indium will increase as the PV industry continues to grow and demand for these commodities or raw materials will someday outstrip supply. When this happens, there will inevitably be upward forces on production costs that will both curtail growth of the thin-film PV industry and prevent thin-film PV from achieving the above-stated goals including a goal of 0.5 $/Wp. Additionally, both indium and tellurium have use in non-PV-related industries that are not subject to the severe cost restraints that face thin-film PV, and these non-PV uses may generate further price pressures on these raw materials.

The concerns over the availability and cost of raw materials has caused many in the PV industry to attempt to develop thin-film PV devices that use materials that are based on abundant and less toxic elements for the thin-film layers including the absorber layer. For example, Cu₂ZnSn(S,Se)₄ or, interchangeably, CZTSS or CZTS (with “S” indicating sulfur, selenium, or a combination thereof) is a compound semiconductor material that has recently been under investigation in the PV industry for use in thin-film PV devices. For example, CZTSS thin films may be p-type and may serve as an absorber layer in thin-film solar cells in place of a thin film of CdTe or CIGS. CZTSS is structurally and chemically similar to more well-known chalcopyrite materials such as CIGS, and CZTSS displays many of the same attributes that have made CIGS a successful material for high-efficiency (i.e., greater than 20 percent efficiencies) thin-film PV devices.

In 2012, a thin-film PV device with a CZTSS absorber was fabricated with an efficiency of 10.1 percent. Such efficiency is remarkably high considering how little research has been done on CZTSS materials by the PV industry. The tested CZTSS film had several characteristics that may have lowered that achieved efficiency. For example, cross-sectional scanning electron microscope (SEM) images indicated that the film had a morphology that included numerous voids and that the grain size was relatively small at less than about 2 microns.

While CZTSS films may someday be used commercially as an absorber in PV devices, the PV industry may demand processes for fabricating higher quality CZTSS films. For example, for CZTSS films to be widely adopted for use in PV devices, there is a demand for CZTSS thin films with bandgaps and doping that are tunable or controllable during or via the manufacturing process to achieve desired optoelectronic and other film characteristics.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

It was recognized that there was potential in investigating use of amorphous/nanocrystalline Cu₂ZnSn(S,Se)₄ or CZTSS (or, more simply, CZTS) film for PV devices. Particularly, tetrahedrally coordinated amorphous chalcogenide semiconductors in the Cu—Zn—Sn—S—Se system were believed to have potential for use as thin-film absorbers in PV devices. Potential benefits of such CZTS films include: (a) the materials are Earth-abundant and non-toxic; (b) the films can be fabricated with low-temperature synthesis (e.g., co-evaporation or sputtering without heating the substrate or the like); (c) fabrication of the films provides low-cost growth on a wide variety of substrates; and (d) the manufacturing methods may be carried out or designed to provide tunable optical and electronic properties (e.g., independent control over optical bandgap and doping in the absorber), which leads to production of optimized single-junction and multi-junction PV devices. The thin films and manufacturing methods described herein differ from prior films and film synthesis at least because the thin films have an unpinned Fermi level due to tetrahedral coordination and also due to the tunability of the opto-electronic properties of the film through heterovalent alloying and/or ambivalent alloying on the cation sublattice.

The material or CZTS thin film may be intentionally synthesized at low temperature (e.g., below 300° C., more preferably below 150° C., and, in some cases, at about room temperature (or, at least, with no heating of the substrate)). Such low temperature deposition/film synthesis is used in order to make the films either amorphous, nanocrystalline, or a blend of amorphous and nanocrystalline. Low-temperature synthesis also leads to a high degree of disorder with respect to the occupancy of cation (Cu, Zn and Sn, or equivalents) coordination shells around the chalcogen species (S and/or Se), whether or not the material is fully amorphous. This disorder with respect to the cation species inhibits the typically undesirable formation of secondary phases such as CuS, ZnS, SnS, and so on, which each have unique crystal structures and a distinct set of physical properties. The disordered material, on the other hand, has physical properties, including optical bandgap and doping level, that can be continuously and/or independently tuned over wide ranges.

In an exemplary method described herein, film compositions are targeted that are complementary mixtures of ZnS (or ZnSe) and Cu₂SnS₃ (and/or Cu₂SnSe₃) according to the approximate formula (1−x)Cu₂SnS₃+ZnS. This will produce films with a Cu/Sn ratio of about two and a (Cu+Zn+Sn)/S ratio of about one, e.g., alloys that are expected to be dominated by tetrahedral coordination of both anion and cation species. Such tetrahedral coordination is useful for unpinning the Fermi level in the material and allowing control over doping levels in the CZTS thin film or absorber. Doping can be achieved by adjustments of cation ratios, which in turn control native point defect concentrations, and/or by the addition of extrinsic dopant species. Independently or in a coordinated manner, optical bandgap may be controlled by the parameter “x” in the formula xCu₂SnS₃+(1−x)ZnS, and carrier concentration may be controlled by varying the ratio Cu/Sn and/or the ratio (Cu+Zn+Sn)/S.

The method of (or thin-film synthesis step of) tuning physical properties by varying cation composition ratios in these materials may be referred to as “heterovalent alloying” because the oxidation states (or valency) of Cu, Zn, and Sn in crystalline CZTS are all different (i.e., in CZTS, the Cu, Zn, and Sn oxidation states are +1, +2, and +4, respectively). However, when these cation species are combined according to the formula (1−x)Cu₂SnS₃+ZnS, the average cation valency in the material remains constant, and this is referred to as heterovalent alloying. Heterovalent alloying is enabled or at least facilitated by the use of low-temperature deposition as the film is disordered, at least to some extent when compared with high temperature synthesis. The heterovalent alloying label for this tuning process distinguishes the method from the more traditional method of tuning the properties of compound semiconductor through “isovalent alloying” in which species that have the same oxidation states of valency are substituted, e.g., In and Ga (both group III elements in the periodic table) in InₓGa₁₋ₓ,As.

For the material system that may be referred to as “a-CZTS” and synthesis method disclosed herein, material properties such as bandgaps in the thin film may also be controlled using standard isovalent alloying, for example by varying the ratio S/Se. Further, though, it may be useful to control or set doping in the thin film through the use of alloying labeled “ambivalent alloying.” An example of ambivalent alloying is adjusting the relative amounts of Cu and Sn in the material while holding Zn constant. Further, the overall ratio of cations to anions is preserved, i.e., (Cu+Zn+Sn)/S. Ambivalent alloying is distinguished from heterovalent alloying, in that, for ambivalent alloying, the average valency of the cation sublattice is not constant.

More particularly, a method is provided for synthesizing a thin film of CZTSS such as for use as an absorber in a photovoltaic device. The method includes providing a substrate in a chamber, and, then, depositing a film of CZTS material on the substrate, the CZTS material comprising copper, zinc, tin, and at least one chalcogen species. The depositing includes tuning an optical bandgap of the film with heterovalent alloying. The depositing is performed at low temperatures, and possibly with the substrate provided in the chamber free of direct/active heating. For example, the substrate may be maintained at a temperature below about 200° C. during the depositing of the film or more commonly below about 100° C.

To implement the method, chalcogen species may be one or more of oxygen, sulfur, selenium, and tellurium. The heterovalent alloying may involve controlling deposition rates (e.g., during co-evaporation) for the copper and the zinc to define a copper to zinc ratio set the optical bandgap such as a value between 0.7 to 3.6 eV (e.g., in the range of 1 to 1.5 eV). The depositing may include, concurrently with and independently from the tuning of the optical bandgap of the film with heterovalent alloying, defining n-type and p-type doping or intrinsic doping of the thin film with ambivalent alloying. Ambivalent alloying typically involves adjusting the copper-to-tin ratio in the thin film.

In addition to the exemplary aspects and embodiments described above, further aspects and embodiments will become apparent by reference to the drawings and by study of the following descriptions.

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1 illustrates a quasi-senary phase diagram in the Cu—Zn—Sn—S—Se system;

FIG. 2 schematically illustrates an accessible range of optical bandgaps for materials in the quasi-quaternary ZnS—Cu₂SnS₃—Cu₂SnSe₃—ZnSe phase system shown in FIG. 1;

FIG. 3 is a graphic/schematic showing a process for independently controlling optical bandgaps and doping level in a-CZTS materials;

FIG. 4 illustrates a graph of optical bandgap values for a variety of a-CZTS materials showing tunability of these values with film compositions such as via heterovalent alloying;

FIG. 5 is a graph showing dependence of valence-band density of states measured on two graded-composition a-CZTS samples showing variances corresponding to increasing/decreasing Cu/Sn and/or cation/anion ratios;

FIGS. 6A-6C illustrate three different solar cells or PC devices that may be fabricated using CZTS thin films as described herein such as for an absorber;

FIG. 7 is a flow diagram for an exemplary method of forming a CZTS thin film such as for use in a PV device; and

FIG. 8 is a graph comparing sheet resistance to Cu-to-Sn ratios for a number of CZTS thin films with differing amounts of Zn.

### DESCRIPTION

The following description is directed generally to a method of fabricating thin-film photovoltaic (PV) devices that include a layer of CZTSS (or, more simply, CZTS). For example, a high-quality thin film of CZTSS may be provided as an absorber or the absorber layer of a thin-film solar cell in the place of a thin film of CdTe, CIGS, or the like. CZTSS (or, more formally, Cu₂ZnSn(S,Se)₄) is a novel class of materials that are being investigated by the PV industry for use as an absorber layer in thin-film PV but that had not been successfully used for such a purpose.

With this demand and lack of prior success in mind, the following describes a new or unique class of Earth-abundant, amorphous chalcogenide semiconductor (AChS) materials for use in single-, tandem-, or multi-junction thin-film photovoltaic (PV) applications. Interestingly, these CZTS films can be synthesized using low-cost and scalable methods such as co-evaporation, sputtering, or the like. A proof-of-concept synthesis and characterization has been successfully completed for amorphous analogs of the Earth-abundant absorber Cu₂ZnSnS₄ (CZTS) and related materials. These results have demonstrated facile ambient-temperature synthesis. Additionally, the fabrication results show that manufacturing may be performed so as to provide independent tunability of key material properties. These controllable or tunable properties include: (1) doping type and level; (2) optical bandgap; and (3) degree of crystallinity for amorphous CZTS (hereafter, a-CZTS) films.

One goal or desire that the methods and thin films (and PV devices including such films) described herein addresses is the PV industry's goal of achieving PV module prices at or below $0.501W, with efficiencies that approach or exceed 20 percent. Thin-film PV technologies including CdTe and CIGS show promise for achieving module prices approaching $0.50/W. Nevertheless, there is concern that the availability of raw materials including tellurium and indium will ultimately limit the growth of these technologies. Current interest in Earth-abundant PV materials, such as CZTS, is motivated by the desire to address these issues, and initial device results for CZTS and CZTSe (or a combination of S and Se) are very promising. To this end, one unique, but non-limiting, embodiment described includes an Earth-abundant, thin-film absorber. The absorber can be deposited at room temperature (e.g., low temperatures such as a temperature falling below a maximum temperature in the range of 150 to 300° C.) on virtually any substrate and, usefully, with independent control over doping levels and optical bandgap.

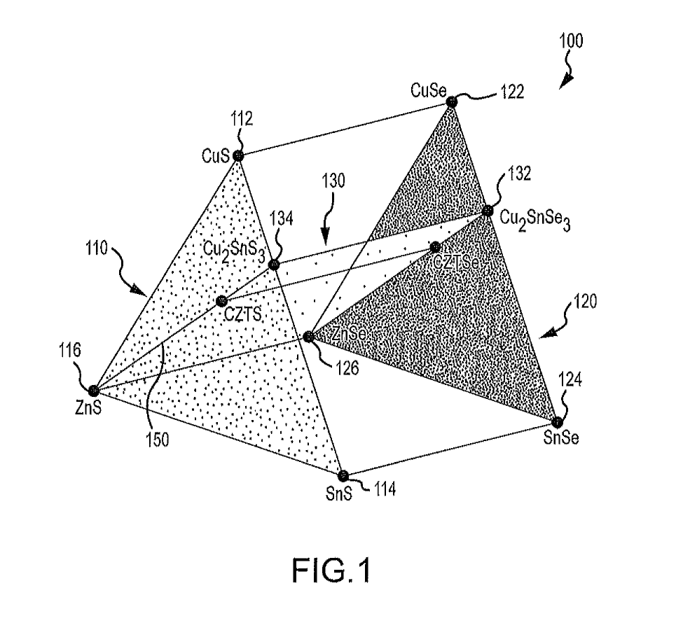

FIG. 1 illustrates a schematic representation of a quasi-senary phase diagram 100 in the Cu—Zn—Sn—S—Se system. The quasi-ternaries in diagram 100 include the CZTS quasi-ternary 110 defined by endpoints 112, 114, 116 corresponding to CuS, SnS, and Zns and the CZTSe quasi-ternary 120 defined by endpoints 122, 124, 126 corresonding to CuSe, SnSe, and ZnSe. The quasi-quaternary 130 or ZnS—ZnSe—Cu₂SnS₃—Cu₂SnSe₃ phase diagram extends between the quasi-ternaries 110, 120 and is defined by endpoints 116, 134, 126, 132 corresponding to ZnS, Cu₂SnS₃, ZnSe, and Cu₂SnSe₃, respectively.

Significant to thin-film synthesis, all phases in the quasi-quaternary 130 are tetrahedrally coordinated semiconductors. The accessible bandgaps for thin-films formed from materials shown in the phase diagram 100 may be: (a) 0.7 eV to 2.7 eV for the CZTSe quasi-ternary 120; (b) 1.0 to 3.5 eV for the CZTS quasi-ternary 110; and (c) 0.7 to 3.5 eV for the quasi-quaternary 130. In crystalline materials, bandgap tunability is achieved through isovalent alloying, e.g., S-Se alloying to form Cu₂ZnSn(S,Se)₄. In contrast, the diagram 100 helps to illustrate that bandgap tunability can be provided based on the concept of heterovalent alloying, enabled by low-temperature deposition of amorphous and/or nanocrystalline materials and involving movement on (or near) the quasi-quaternary 130 between the CZTS quasi-ternary 110 and the CZTSe quasi-ternary 120. One skilled in the art will understand that, while the quasi-quaternary 130 is shown as a slice or as being planar, it may be considered a slab with a thickness as the thin-films described herein may fall at a location off the quasi-quaternary 130 of diagram 100 and still obtain acceptable qualities of an absorber for a PV device.

The diagram 100 and experimental work has shown that an a-CZTS thin film (i.e., amorphous or disordered CZTS films) can be deposited at room temperature and that optical bandgap can be controlled by varying film composition. A subset of such materials have been identified with compositions close to crystalline phases on the Cu₂SnS₃-CZTS-ZnS tie line 150 in the quasi-ternary CuS—ZnS-SnS system 110 that are characterized by tetrahedrally coordinated sulfur anions and metal cations. Amorphous compositions along this tie line 150 can be denoted as Cu₂₍₁₋ₓ₎ZnₓSn₁₋ₓS₃₋₂, (0≦x≦1).

Tetrahedral symmetry has effects on the electronic structure of these materials that make them highly or at least more suitable for use in thin-film PV devices. In particular, studies have indicated that tetrahedral symmetry in amorphous semiconductors plays a key role in unpinning the Fermi level in these materials and allowing them to be doped. Along these lines, it has been demonstrated that the Fermi level in the system 130 is unpinned and that doping levels can be controlled by adjusting film composition. Stated differently, FIG. 1 provides with diagram 100 an overview of the tetrahedrally coordinated amorphous chalcogenide semiconductor (AChS) materials with slice/slab 130.

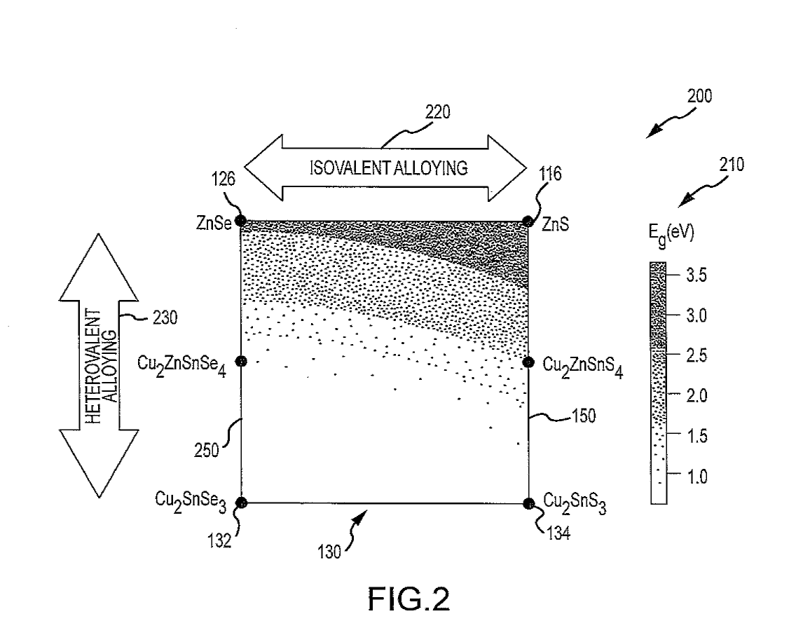

FIG. 2 shows with schematic 200 the accessible range 210 of optical bandgaps for these materials, i.e., optical bandgaps in the quasi-quaternary ZnS—Cu₂SnS₃—Cu₂SnSe₃−ZnSe phase system 130. Isovalent alloying 220 is shown with movement of composition between tie lines 150 and 250 while heterovalent alloying 230 is shown with movement of composition within phase system 130 parallel to the tie lines 150, 250. As will be understood from FIGS. 1 and 2, heterovalent alloying, with or without Isovalent alloying, may be used during synthesis to tune or control the bandgap of the thin film fabricated to fall within the system 130 such as to achieve an absorber with a bandgap of 0.8 to 2.5 eV or the like to suit a particular PV device or other thin-film application. It should be noted that graph 200 was constructed using optical bandgaps from crystalline materials as proxies for the amorphous materials and bandgaps will likely tend to be lower in the amorphous materials but conclusions regarding bandgap tuning over a wide range still is applicable.

The schematic 200 provides a mapping of potentially accessible optical bandgaps 210 in the amorphous quasi-quaternary 130. Amorphous-phase bandgaps at the vertices 116, 126, 132, 134 are assumed to be similar to the corresponding crystalline-phase bandgaps. Optical bowing parameters that correctly reproduce bandgaps for CZTSe and CZTS have also been estimated to provide the schematic 200.

One objective of this teaching is to provide or develop a-CZTS materials for thin-film PV applications. With this in mind, the following exemplary description teaches materials and device structures that are particularly well-suited for thin-film PV applications including single- and multi junction devices that can be deposited using high-throughput, low-cost manufacturing methods.

With regard to amorphous chalcogenide semiconductors, amorphous solids inherit their physical properties from crystalline analogs. Broadly speaking, materials that are semiconductors in the crystalline phase are also semiconductors in the amorphous phase and, likewise, for insulating and metallic phases. This inheritance of physical properties derives largely from nearest-neighbor chemical interactions and coordinations, which tend to be very similar in crystalline and amorphous phases of the same material. A distinct feature in amorphous semiconductors that arises from the lack of long-range order is the existence of pronounced valence- and conduction-band tails that extend into the gap. These band tails typically fall off exponentially in energy, and, as concentrations fall below a critical threshold, the band-tail states become localized. This leads to the formation of a mobility gap, which may be defined as the region between de-localized states in the valence and conduction bands.

As a consequence, conduction in amorphous semiconductors can occur in the usual manner, i.e. band conduction, and also via the variable-range hopping mechanism in which charge carriers hop between localized states in the gap. A disadvantage of amorphous materials is that transport properties tend not to be as good as in crystalline phases. On the other hand, a significant advantage of these materials is a high degree of tunability of material properties. The methods described herein may be thought of as exploiting the tunability aspect or property to adjust optical bandgaps in an a-CZTS thin film. Adjustments or tuning may be over a broad continuum from at least about 1.0 eV to about 2.75 eV. Bandgap control may be performed with heterovalent alloying using compositions roughly defined by the ratios of Cu/Sn being about 2 (e.g., about 1.3 to about 23) and (Cu+Sn+Zn)/(S+Se) being equal to about 1 (e.g., about 0.75 to 1.25). These ratios are useful for producing tetrahedrally coordinated amorphous/nanocrystalline disordered semiconducting phases over the entire range in the thin film (or PV device absorber).

At this point, it may be useful to explain why it is desirable to provide a CZTS thin film with tetrahedral symmetry. Briefly, traditional AChS materials (e.g., compounds of groups V and VI elements, including a-As₂S₃, a-As₂Se₃, a-Sb₂S₃, etc.) are characterized by 2- and 3-fold nearest-neighbor coordinations. Doping these materials is difficult in part due to the negative effective electron correlation energies (negative U_{eff}) between unpaired-electron dangling bonds. Negative U_{eff} derives from a lack of rigidity in low-coordination amorphous networks, and it leads to high and nearly equal concentrations of positively and negatively charged defects that effectively pin the Fermi level at mid-gap.

In contrast, though, the situation is very different for tetrahedrally coordinated materials. Because there are more nearest-neighbor interactions, tetrahedrally coordinated amorphous networks are more rigid, which makes U_{eff} positive so that the majority of dangling-bond electrons remain unpaired. Consequently, dangling bonds can be passivated (e.g., hydrogen passivation of a-Si), which removes deep levels associated with these defects, increases minority-carrier lifetime, unpins the Fermi level, and allows both n-and p-type doping through the addition of extrinsic dopants. The challenge for developing successful AChS thin-film PV materials may be broken into the following two parts: (1) identification of AChS material systems characterized by tetrahedral coordination, in which the Fermi level can be unpinned to allow n- and p-type doping; and (2) development of methods to passivate dangling-bond defects that act as recombination centers and limit minority-carrier lifetimes and mobilities.

It was recognized that, similar to other PV materials including Si, III-V compounds, CdTe, and CIGS, crystalline CZTS is a tetrahedrally coordinated semiconductor. CZTS and related materials ZnS and Cu₂SnS₃ are composed of tetrahedrally coordinated metal-cation and sulfur-anion sublattices. Furthermore, a-CZTS materials have been synthesized and tested, and this prototyping or proof-of-concept synthesizing demonstrates unpinning of the Fermi level and independent control over doping and optical bandgap.

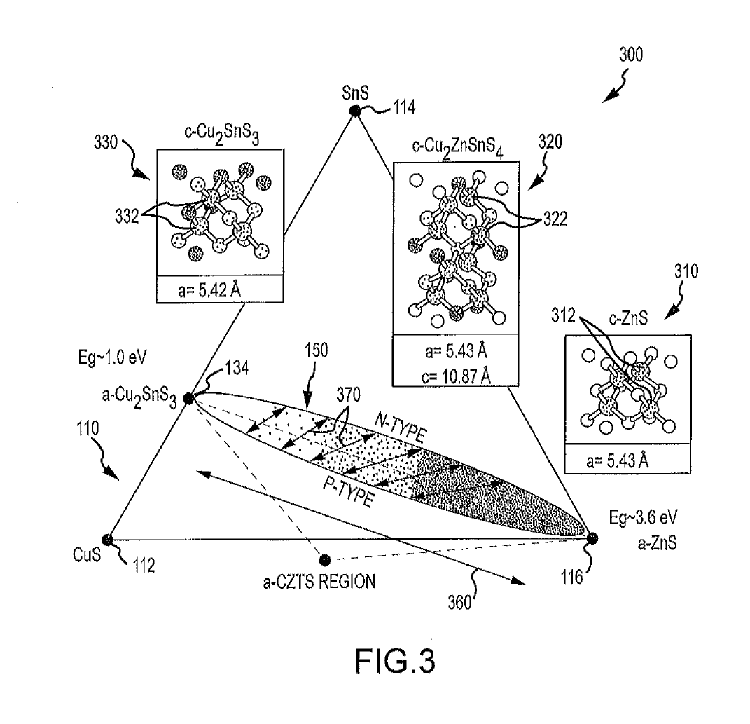

FIG. 3 illustrates with graphic/schematic 300 an approach to independently control optical bandgaps and doping level in a-CZTS materials. Particularly, heterovalent alloying is shown with arrow 360 between points 116 and 134 along tie line 150 in the quasi-ternary CuS—ZnS-SnS system 110. The heterovalent alloying includes or involves varying 360 compositions along the Cu₂SnS₃—ZnS tie line 150, which results in bandgaps covering at least the range 1.0 eV<E_{g}<2.75 eV. Ambivalent alloying is shown with mows 370 within the tie line (transverse to alloying line 360). As shown with arrows 370, doping is controlled as varying copper and/or sulfur content makes the material (CZTS thin film being deposited/synthesized) more or less p-type or n-type such as through changes in native point defect concentrations (e.g., change charge carriers to independently choose doping in a thin film).

As shown with schematic 300, the ZnS-CZTS-CTS tie line 150 in the quasi-ternary CuS—ZnS—SnS phase system 110 is defined by tetrahedral coordination. As shown at 310, 320, and 330, respectively, these compositions have similar unit cells with the tetrahedral coordination of each shown at 312, 322, 332. These unit cells 310, 320, 330 have nearly identical lattice constants, too, and common anion sublattices. Further, it is likely these compositions will provide a high degree of defect tolerance based on experience with crystalline CZTS (or c-CZTS).

FIG. 3 may be thought of as providing a schematic quasi-ternary phase diagram 300, which shows the independent tunability of the optical bandgap via line 360 and doping type via lines 370 for a-CZTS materials. Initial work and testing has indicated that bandgaps can be varied along arrow 360 continuously along the Cu₂SnS₃—ZnS tie line 150 by varying the Zn/(Cu+Sn) ratio. Furthermore, the extent of p-type doping directly correlates to the Cu content as shown with lines 370. Insets 310, 320, 330 show the unit cells for crystalline Cu₂Sn₃, CZTS, and ZnS, and each of these are tetrahedral semiconductors with very similar unit cells and lattice constants. Again, arrows 370 in the a-CZTS region 150 indicate Cu addition/subtraction may be used for doping control during synthesis of a CZTS thin film.

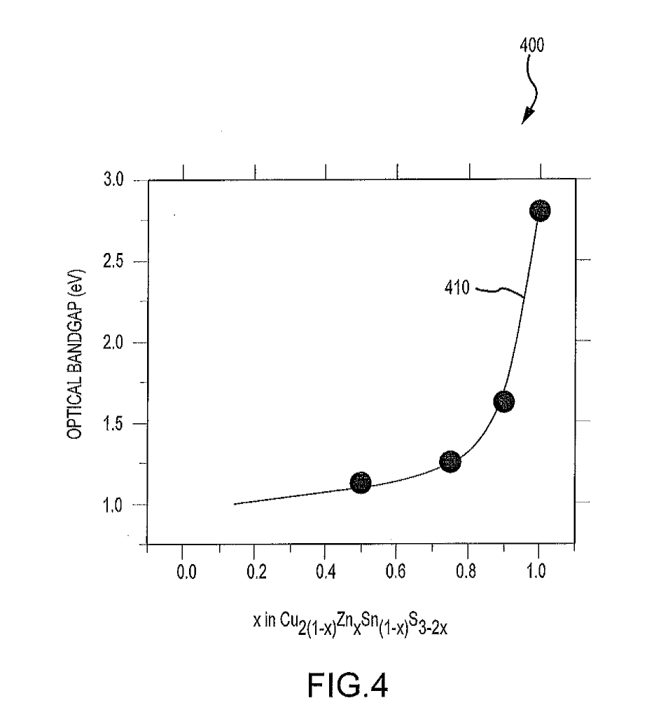

Based on the above discussion, it should be evident that tetrahedral amorphous chalcogenide semiconductors (AChS) or thin films may be effectively synthesized at low temperatures with effective control over bandgaps and doping. With regard to bandgap control, optical bandgap in a-CZTS materials can be adjusted by alloying along the Cu₂SnS₃—ZnS tie line or via S-Se alloy compositions. In the former case, varying x in Cu₂₍₁₋ₓ₎ZnₓSn₁₋ₓS₃₋₂, (0≦x≦1) yields materials with bandgaps ranging from about 1.0 eV to about 2.75 eV. Sulfur-selenium alloy compositions (e.g., Cu₂ZnSnS_{4(1-y})Se_{4y} with 0≦y≦1) produce bandgaps down to ˜0.7 eV. Testing has shown that the bandgap of a-CZTS materials varies with composition roughly as expected, as shown in FIG. 4.

FIG. 4 illustrates a graph 400 comparing with line 410 the optical bandgap value to the value of “x” in the above chemical formula. In other words, line 410 shows the optical bandgaps for a-CZTS materials (e.g., a thin film or absorber of a PV device). The value for a-CZTS was measured/extracted from transmission reflection measurements of a synthesized thin film (which is suited for use as an absorber). The value for a-CTS was estimated from in situ real-time spectroscopic reflectrometry (RTSR) data.

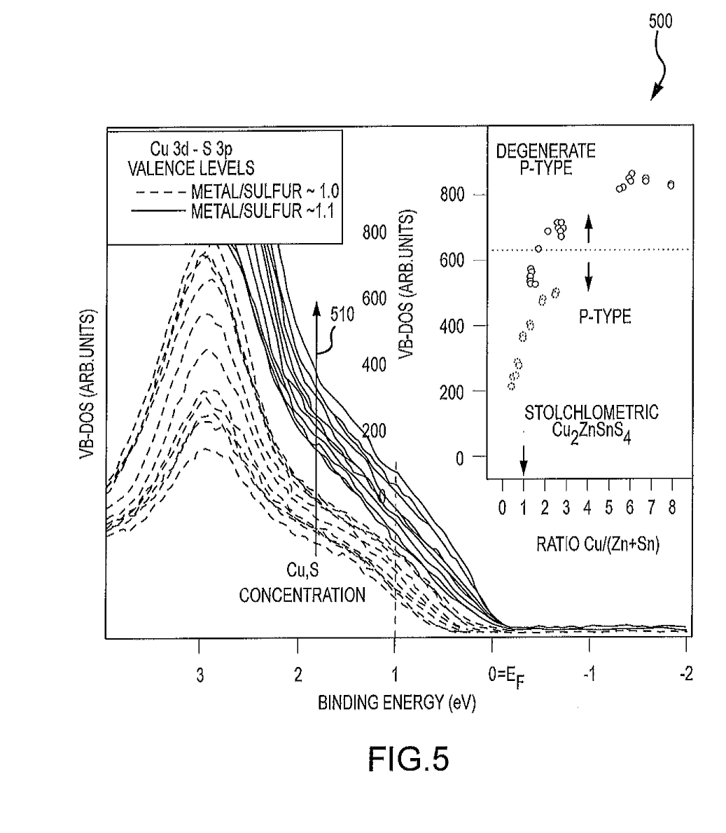

With regard to the control of doping in the CZTS thin film, FIG. 5 illustrates a graph 500 illustrating the effects of compositional variations (e.g., increasing Cu, S concentrations shown with arrow 510) on the valence-electronic structure of a-CZTS films as measured by X-ray photelectron spectroscopy (XPS). In the valence-band (VB) XPS data, there is a systematic shift of the VB edge toward the Fermi level with increasing concentration of either Cu or S. In XPS spectra, the binding-energy (BE) scale is referenced to the Fermi level, E_{F}, according to BE(E_{F})=0 eV. The valence-band maximum (VBM) is extracted from XPS data by the intersection of a straight-line fit to the VB edge with the x-axis.

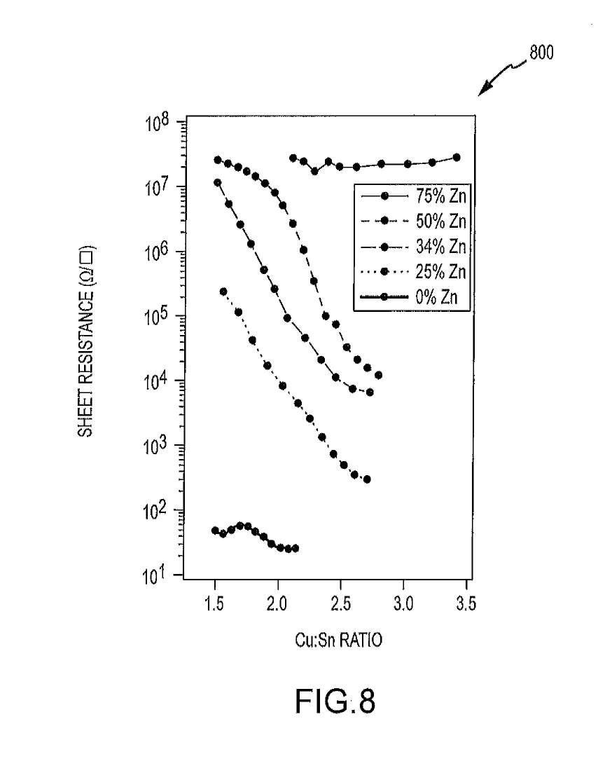

A shift of the VBM toward E_{F} indicates p-type doping, and the appearance of a Fermi edge at E_{F} in the VB spectra in Cu- and S-rich samples is definitive proof for degenerate p-type doping. Degenerate p-type doping was also verified by measurements of low values of electrical resistivities measured in these samples. At the other extreme in this sample set (Cu-poor), the Fermi level is located near the middle of the optical bandgap, which indicates that this film composition behaves as an intrinsic semiconductor. FIG. 8 illustrates a graph 800 comparing sheet resistance to Cu-to-Sn ratios for a number of CZTS thin films with differing amounts of Zn, and the graph 800 is useful for showing how electrical properties such as sheet resistance can be tuned or controlled by adjusting the Cu-to-Sn ratio and/or by adjusting the percentage of Zn provided in a CZTS thin film fabricated according to the method taught herein.

The observed influence of Cu content in a-CZTS films on doping level is essentially identical to those observed recently in experiments on crystalline CZTS materials and can be understood in terms of variations in native point-defect concentrations. Copper-on-zinc (Cuz_{Zn}) antisite defects acting as acceptors are the most likely explanation for the observed p-type behavior. This view is supported by first-principles calculations on crystalline CZTS showing that the formation energy for Cu_{Zn} antisite defects is relatively low, e.g., on the order of −0.2 eV to −0.3 eV, which indicates that these defects should form readily under Cu-rich conditions. Similarly, excess sulfur creates p-type doping via cation vacancies acting as acceptors.

The graph 500 of FIG. 5 shows the dependence of valence-band density of states (VB-DOS) measured on two graded-composition a-CZTS samples (shown with dashed and solid lines corresponding to metal/sulfer ratio of about 1 and about 1.1, respectively). These results show that it is possible to unpin the Fermi level and then to control doping level in this system via intrinsic point defects, thereby demonstrating tunable electronic properties for these a-CZTS thin films. The inset shows the VB-DOS measured at 1 eV for each of the film compositions. Higher Cu or S concentrations systematically lead to higher levels of p-type doping. In the most highly doped films, appearance of a Fermi edge indicates degenerate p-type behavior.

With the above factors in mind, thin film deposition methods may also be designed or configured to achieve doping levels in the range from intrinsic to degenerate n-type. For example, the following two strategies for n-type doping may be followed: (1) doping control via native point defects; and (2) doping control through extrinsic dopants. Results using the first strategy show that Cu- and S-rich compositions produce p-type behavior. Therefore, it may be useful to use Cu- and/or S-poor compositions as potential routes to n-type material. N-type doping in ZnS has been achieved using S-poor growth conditions in which sulfur vacancies acts as donors and also using extrinsic dopants including Al and Cl. Any of these doping schemes can likely be used successfully in a-CZTS materials.

Because sulfur plays the same role in all a-CZTS compositions, the S-poor doping strategy may be useful across the entire compositional range from a-Cu₂SnS₃ to a-ZnS. Al dopants substituting on Zn sites may provide a route toward n-type doping, especially in Zn-rich compositions. Similarly, a Cl atom on a sulfur site is expected to act as a donor and, in the a-CZTS system, has the additional benefit of being a potential passivating agent for cation dangling-bond (DB) defects. It is, therefore, possible that Cl could serve a dual purpose of simultaneously passivating cation DB defects while acting as an n-type dopant in an S-poor a-CZTS material.

At this point, it may be useful to briefly discuss amorphous-nanocrystalline-microcrystalline phase control as part of a thin film deposition process. Experiments can be used to determine or better define growth conditions that lead to amorphous and nanocrystalline phase films. Additionally, annealing conditions can be determined as a function of film composition to optionally induce crystallization in amorphous films or cause grain growth in nano-crystalline films. For example, a-CZTS growth chamber may be provided that incorporates an in situ real time spectroscopic reflectometry (RTSR) system. RTSR is a sensitive probe of optical properties of films and is used to monitor crystalline mole fraction versus temperature for samples deposited as amorphous films at low temperature and heated in vacuum in experiments designed to probe the crystallization kinetics of these materials.

With regard to strategies for bulk-defect passivation and to effectively synthesize a-CZTS materials suitable for PV applications, it may be useful to develop robust and scalable methods for passivating bulk defects, either during growth or via post-processing. Un-passivated amorphous materials have short drift diffusion lengths and minority-carrier lifetimes. To mitigate these effects, various methods for passivation of bulk dangling bond defects can be used and further explored. One strategy may be to grow films under sulfur-rich conditions to minimize under-coordinated cation species that lead to cation dangling bond defects. This strategy may produce increased concentrations of under-coordinated sulfur atoms so that S-rich growth conditions are coupled with the introduction of low-electronegativity species such as Li, Na, or K that are capable of passivating sulfur dangling bond defects. Such a strategy might work best for producing passivated p-type films, as it has been demonstrated that S-rich films tend to be more p-type.

A second bulk-defect passivation strategy is to grow sulfur-poor films, coupled with high-electronegativity species such as F and Cl that can passivate cation dangling bond defects. As a dopant, a chlorine atom substituting on a sulfur site acts as an acceptor and has been used as an n-type dopant in ZnS. Therefore, this second strategy may be another useful route to provide passivated n-type material. Passivation methods based on the introduction of compounds that supply both low- and high-eleetronegativity species (e.g., LIF, NaF, HCl, and the like), which could simultaneously passivate both anion and cation dangling bonds, may also be used or further explored as a route to provide passivated intrinsic materials in a thin film. Achieving the full range of doping from degenerate p-type to intrinsic to degenerate n-type enables development of critical device sub-components, including p/i/n and p⁺/n⁺ tunnel-junction structures, as discussed in the following description.

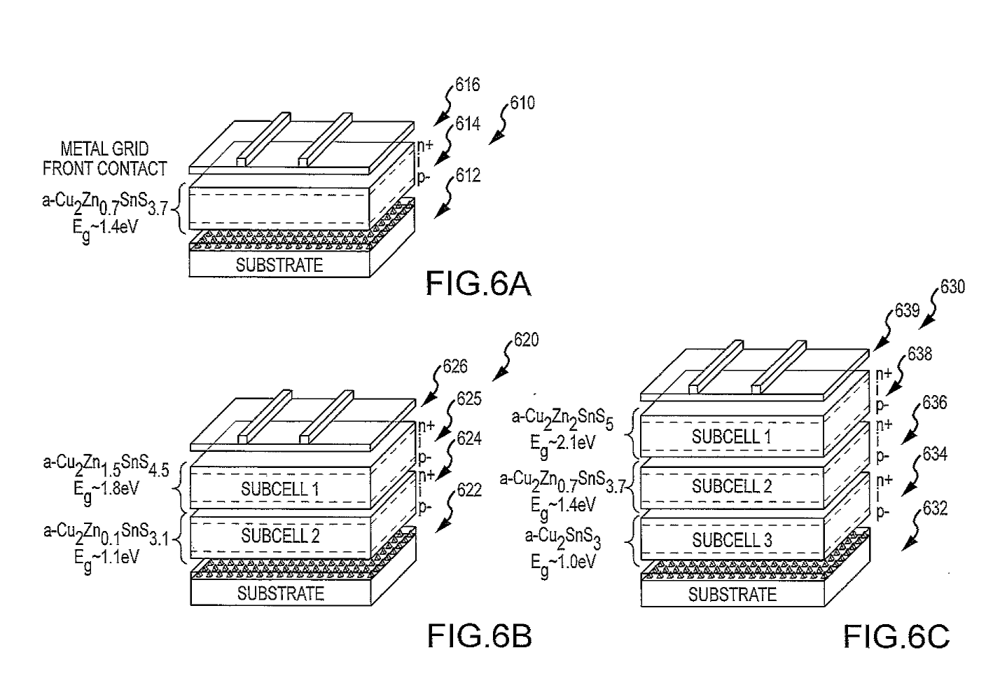

FIGS. 6A-6C illustrate three different solar cells or PC devices 610, 620, 630 that may be fabricated using CZTS thin films as described herein such as for an absorber. FIG. 6A shows a single junction design with subcell or absorber 614 sandwiched between a substrate and/or back contact 612 (e.g., a plasmonic back contact or the like) and a front contact/metal grid 616.

The absorber or subcell 614 is formed by depositing or synthesizing a thin film of a-CZTS material on the upper surface for of the substrate/back contact 612. For example, this may be performed without heating the substrate (e.g., at room temperature or with a source heater causing the substrate to be heated but below some predefined maximum temperature associated with low temperature deposition such as a maximum temperature in the range of 150 to 300° C.). The deposition may be performed using co-evaporation or other techniques such as sputtering, and, as discussed above, post-deposition processing may be performed to obtain the final absorber/subcell configuration 614. As discussed above, heterovalent alloying may be used during deposition to control or select the bandgap of the absorber/subcell 614 (e.g., between about 1.0 and about 2.75 eV with 1 to 1.5 eV being useful in many cases). With this in mind, FIG. 6A provides a non-limiting example of an absorber 614 formed via a deposited/synthesized a-CZTS thin film made up of a-Cu₂Zn_{0.7}SnS_{3.7} with a bandgap of about 1.4 eV. Further, the doping has also been controlled during deposition as shown between n-type and p-type doping such as via ambivalent alloying during co-evaporation or other deposition processes.

FIG. 6B shows a PV device 620 with a two junction design. The device 620 includes a pair of subcells/absorbers 624, 625 sandwiched between the substrate/back contact 622 and the front contact 626. The use of a-CZTS for subcells 624, 625 allow the bandgaps to be tuned (via heterovalent alloying) to differ with the upper or top subcell 625 having a higher bandgap value (e.g., 1.5 to 2.0 eV or the like with 1.8 eV shown as an example) and with the lower or bottom subcell 624 having a lower bandgap value (e.g., 1 to 1.5 eV or the like with 1.1 eV shown as one useful example). Again, ambivalent alloying may also be used during deposition to tune or control doping to achieve the n-type and p-type doping shown in FIG. 613. In this non-limiting example, the composition providing these bandgaps are a-Cu₂Zn_{1.5}SnS_{4.5} in the subcell 625 and a-Cu₂Zn_{0.1}SnS_{3.1} in the subcell 624.

FIG. 6C shows a PV device 630 with a three junction design. The device 630 includes three subcells/absorbers 634, 636, 638 sandwiched between the substrate/back contact 632 and the front contact 639. The a-CZTS is synthesized to set or tune the bandgaps of each subcell 634, 636, 638 by setting the compositions (e.g., via heterovalent alloying) and also to control doping as shown. The 3-junction design allows the bandgaps to be tuned to increase between the front and back contacts 639, 632 so as to more effectively absorb energy from received light. The bandgaps used may vary with the device 630 shown as using 2.1 eV, 1.4 eV, and 1.0 eV as on example with it being understood that these could be any decreasing values such as ones falling in the ranges of 1.5 to 2.5 eV, 1.2 to 1.8 eV, and 0.8 to 1.3 eV, or the like. Also, the compositions will vary with the desired or tuned bandgaps with the illustrated compositions being a-Cu₂SnS₃ for subcell 634, a-Cu₂Zn_{0.7}SnS_{3.7} for subcell 636, and a-Cu₂Zn₂SnS₃ for subcell 638.

FIGS. 6A-6C are useful for showing that the methods taught herein allow PV devices to be designed and fabricated with low-temperature deposition of the absorber layers/films while also allowing bandgap and doping to be independently controlled by using alloying techniques (deposition rates) to set these values within desired ranges for each subcell/absorber layer. These figures show conceptual solar cell designs based on a-CZTS materials with one, two, and three junctions. Nanostructured plasmonic back contacts may be used for contacts 612, 622, 632 to more effectively harvest photons. Absorber compositions fall along the Cu₂SnS₃-ZnS tie line, so that the Cu/Sn ratio is about two and the (Cu+Zn+Sn)/S ratio is about one. Device structures like these based on p/i/n junctions are, of course, only one non-limiting possibility that will be considered by those skilled in the art based on the present teaching.

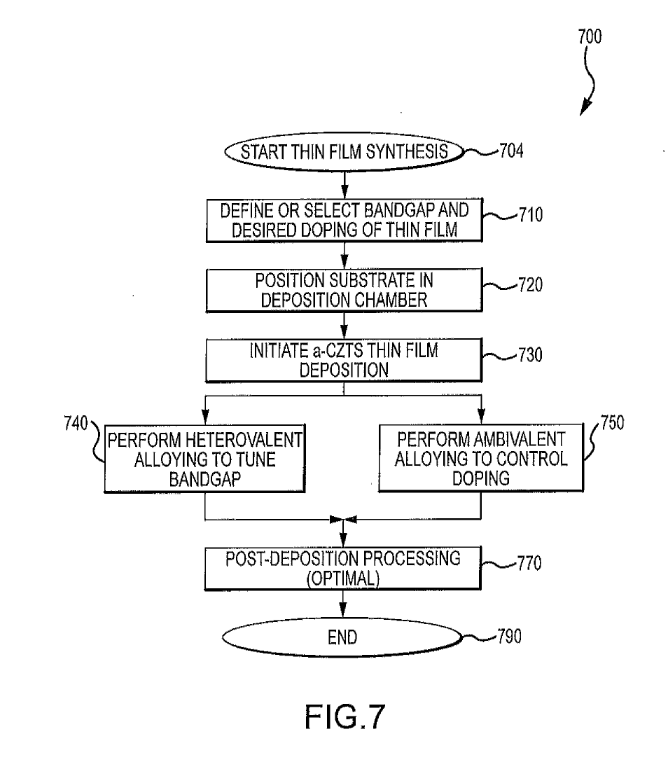

FIG. 7 illustrates a flow diagram or chart 700 showing a thin film synthesis that may be performed based on the previous description and concepts. The method 700 starts at 704 such as with selection of a PV device for which an absorber or similar thin film component would be useful and for which an a-CZTS films as described herein is well suited. At 710, the method 700 includes defining or selecting a bandgap for the film (e.g., a bandgap between about 1.0 to about 2.75 eV such as between 1 and 1.5 eV or the like) and also doping in the film may be designed or chosen at step 710. At 720, a substrate such as a back contact for a solar cell is positioned within a deposition or synthesis chamber, and, significantly, the chamber may be designed or controlled such that the substrate is not directly heated (e.g., the method 700 can and should be performed with the substrate at room or another low temperature).

At 730, the method 700 continues with initiating a-CZTS thin film deposition on an exposed surface of the provided substrate. In the case of co-evaporation, this may involve heating a number of sources to provide the materials of the a-CZTS film. The method 700 then includes separately or independently performing heterovalent alloying 740 and ambivalent alloying 750 to tune or control the bandgap of the thin film and doping. As discussed previously with regard FIGS. 1-3, this may involve controlling the addition of particular materials such as copper, zinc, sulfur and/or selenium, or the like to set ratios of materials while remaining within the quasi-quaternary ZnS—ZnSe—Cu₂SnS₃-Cu₂SnSe₃ system or tie line. Such alloying may be performed by adjusting or setting the deposition (evaporation) rates for the various materials making up the synthesized a-CZTS film so as to achieve the desired ratios or material quantities.

At 770, post-deposition processing may optionally be performed on the deposited film of a-CZTS materials such as to passivate bulk defects as discussed above. At step 790, the method 700 ends, and the thin film and substrate may be used in a PV device such as the ones shown in FIGS. 6A-6C.

It should be noted that Tauc analysis of transmission/reflection data was performed for thin film samples fabricated according to the description provider herein including bandgap engineering via heterovalent alloying. In this analysis, optical properties of Zn-rich films were tested with regard to increasing optical energy and varying the quantity of zinc and/or copper in the thin film. The Tauc analysis verified bandgap tunability over the range of 1.25 eV to 2.75 eV. The Tauc plots also indicated a high degree of disorder consistent with amorphous/disordered material and also absorption coefficients greater than 10⁴ cm⁻¹.

The CZTS films may be thought of as a novel class of amorphous chalcogenide semiconductor (AChS) and nano-crystalline chalcogenide (nc-ChS) materials within the Cu—Zn—Sn—S—Se system, which can be synthesized by a simple, scalable, and manufacturing-friendly process at low temperature. The chalcogen species is referred to as “S” where, in fact, it can incorporate oxygen, sulfur, selenium, tellurium, or a combination of these materials depending on the application and the desired physical properties.

The physical properties of these materials are derived from those of the quasi-ternary Cu₂S—ZnS—SnS₂ (or CuS—ZnS—SnS) system, which includes the thin-film absorber material Cu₂ZnSnS₄ (CZTS). When formed under appropriate processing conditions, these AChS materials are characterized by predominant tetrahedrally coordinated chalcogen atoms, as is the case for well known crystalline semiconducting materials. The above thin film synthesis methods and designs exploit the connection between crystalline and amorphous phases analogous to that between crystalline silicon PV technologies and hydrogen-passivated amorphous silicon.

The inventors have performed basic synthesis and characterization of amorphous and nano-crystalline CZTS analogs (hereafter, a-CZTS and nc-CZTS). The results indicate that key material properties can be controlled including: (a) p-type or intrinsic doping; (b) doping level (intrinsic to p-type); (c) position of the valence-band maximum relative to the Fermi level; (d) optical bandgap; and (e) crystallinity (from amorphous to nano- or micro-crystalline).

The methods described herein allow thin-film a-CZTS synthesis via a single-step process in which the substrate is exposed to both metal and chalcogen species to directly form the semiconducting material. Whereas nano- or micro-crystalline films form at elevated deposition temperatures, investigations have indicated that amorphous films can be deposited at ambient temperatures, i.e., without active substrate heating. Furthermore, the experimental results indicate that a-CZTS and nc-CZTS materials possess all of the baseline requirements for use as a thin-film absorber, including tunable optical bandgaps in the range from about 1.4 to about 1.7 eV, high absorption coefficients (e.g., about 10⁴ cm⁻¹), and p-type doping.

In one synthesis process, the CZTS material was deposited as a thin film using co-evaporation (e.g., according to the formula: xCu(v)+yZn(v)+zSn(v)+4S(v)→CuₓZn_{y}Sn_{z}S₄ (s)). In this formula, the chalcogen can either be supplied from a valved cracking source (e.g., S₂, sulfur dimers) or from an elemental source (Sₙ, with n=2 to 8). Amorphous and nano-crystalline film depositions have been achieved under conditions where the substrate was not actively heated during deposition, except from stray heat from the deposition sources.

Alternatively, Zn and Sn can be provided in the form of vapor-phase mono-sulfides (and/or selenides) from bulk ZnS and SnS source materials. This ensures that about half of the sulfur incorporated into the film originates from metal-chalcogenide species. In turn, this could help to maximize the amounts of the beneficial tetrahedrally coordinated chalcogen atoms, which controls the number of chalcogen dangling bonds (metal vacancies) that may be responsible for p-type doping. In this case, synthesis proceeds according to the formula: xCu (v)+yZnS (v)+zSnS (v)+(4-y-z)S (v)→CuₓZn_{y}Sn_{z}S₄ (s).

A well-known problem with AChS materials that has thus far prevented their use in thin-film PV devices is that these materials are generally characterized by doubly coordinated chalcogen atoms. This leads to pinning of the Fermi level in the middle of the bandgap and, consequently, an inability to dope these materials. In some material systems, however, it has been demonstrated that p-type doping is possible in cases where the majority of chalcogen atoms are tetrahedrally coordinated to four nearest-neighbor metal cations, as they are in certain crystalline chalcogenide semiconductors such as CZTS. The inventors verified that tetrahedral chalcogen coordination and p-type doping can be achieved in the Cu—Zn—Sn—S system by controlling the metal-to-chalcogen ratio during growth of the thin film.

Particularly, a series of measurements on combinatorially graded films demonstrated an ability to affect the doping level by controlling both the metal-to-chalcogen ratio (M/Ch) and the Cu/(Zn+Sn) ratio. The results of these measurements strongly imply that both excess sulfur (cation vacancies) and contributions from the Cu3d levels to the valence band play dominant roles in determining both the doping level as well as the position of the valence-band maximum.

With the above discussion in mind, it may be useful to again return to some of the guiding design parameters or goals, e.g., to provide device designs to achieve 20-percent efficent PV modules at $0.50/W, and discuss how use of a-CZTS provides devices addressing these design issues. As discussed with reference to FIGS. 6A-6C, solar cell designs can be specifically tailored to this novel material system to enhance performance. Lifetimes and mobilities in amorphous materials tend to be lower than in crystalline phases. Hence, there is the potential of p/i/n device structures will mitigate these previously experienced effects with a-CZTS devices. This may have positive impacts on J_{SC}, V_{OC} and FF and also improve device performance.

Also, advanced light-trapping schemes based on plasmonic/photonic back-contact structures may be useful to enhance efficiency of a-CZTS-based PV devices. Such PV devices may also be designed to make use of conventional light-trapping schemes, such as textured substrates and high-haze transparent conducting oxide (TCO) layers. Enhanced light-trapping enables the use of thinner active layers, so that minority carriers can be efficiently collected before they recombine, increasing J_{sc}. A second benefit of thinner active layers may be increased throughput in deposition tools in manufacturing, which may directly reduce module cost. In some embodiments, plasmonic grating structures may be provided at the back contacts of a-CZTS devices. Nanostructured plasmonic back contacts in thin-film solar cells effectively couple light into thin absorber layers via surface plasmon polaritons and improve device performance. While these advanced light-trapping schemes are still in the early stages of development, they seem particularly well suited to amorphous materials like a-CZTS, which may produce smooth and uniform films. Additionally, optical techniques for nano-patterning AChS materials have been demonstrated, opening the possibility that these techniques could be used to imprint photonic structures directly into the active layers of a device.

Tandem and multijunction approaches can boost efficiencies relative to comparable single-junction devices through more efficient use of the solar spectrum and increasing V_{OC}. For high-deposition rate amorphous materials, the added cost of depositing two or more subcells in a device stack could easily be offset by the resulting efficiency gains. Cost modeling indicates that a three junction a-CZTS device (as shown in FIG. 6C) would be at least 10 percent less expensive to manufacture than a CIGS module of comparable efficiency. The a-CZTS cost-model was based on the well-understood cost models for CIGS modules on glass substrates, using 2011 cost inputs, and assumes only that a-CZTS layers could be deposited 5 times faster than CIGS. The latter is a conservative estimate, considering that for amorphous materials there is no need for grain growth. The cost-model does not account for cost savings associated with elimination of substrate heating in a-CZTS deposition or with roll-to-roll manufacturing for which a-CZTS seems particularly well suited. The same conservative cost-model analysis showed that due to lower manufacturing costs, a 17.5 percent triple-junction a-CZTS module would be cost-competitive with a 20 percent-efficient CIGS module.

Combining all of the strategies discussed above, including optimal device architecture (improved J_{SC}, V_{OC} and FF), efficient light-trapping (increased J_{SC}), and multiple junctions (increased V_{OC}), provides a potential pathway toward 20 percent efficient modules that reduce balance of systems costs consistent with achieving a $0.50/W module price goal. Hence, it seems clear that the CZTS thin film technology described herein has the potential to be cost-competitive with other PV technologies.

The above may be obtained by synthesizing a-CZTS materials, mapping the ranges of bandgap and doping tunability, and determining growth conditions that lead to amorphous or nano-crystalline materials. Material properties may be optimized for PV applications, with a strong focus toward developing methods for bulk-defect passivation to maximize minority-carrier lifetimes and carrier mobilities. The possible existence of light-induced metastabilities can also be further explored. Solar cell designs specifically tailored for the properties and characteristics of a-CZTS materials can readily be developed.

With regard to combinatorial growth, thin-film a-CZTS synthesis may be performed via elemental or binary co-evaporation. The deposition system incorporates capabilities for both uniform and combinatorially graded thin-film deposition. Additionally, these deposition processes provide or support capabilities to pattern small-area device structures on combinatorially graded film stacks so as to facilitate measurements of material properties and correlations thereof with device performance.

While a number of exemplary aspects and embodiments have been discussed above, those of skill in the art will recognize certain modifications, permutations, additions, and sub-combinations thereof. It is therefore intended that the following appended claims and claims hereafter introduced are interpreted to include modifications, permutations, additions, and sub-combinations to the exemplary aspects and embodiments discussed above as are within their true spirit and scope.

It is likely that use of a-CZTS materials for thin films of PV and other devices may have numerous impacts. These a-CZTS materials have the potential to revolutionize photovoltaics and enable high-performance, low-cost terawatt-level PV with module costs at or below $0.501W. These materials are based on earth-abundant and non-toxic raw materials that will enable low-cost PV modules even at very high annual production levels, with no materials scarcity issues. Amorphous material lends itself to rapid synthesis, potentially much faster than other thin-film PV technologies, including a-Si, which directly lowers module costs by increasing throughput in deposition tools.

Independently tunable bandgap and doping levels enable tandem or multi-junction PV devices, which could cost-effectively boost module efficiencies close to 20 percent. Low-temperature deposition facilitates tandem device structures by mitigating difficulties associated with interdiffusion between adjacent layers during processing at elevated temperatures. Low-temperature deposition is compatible with roll-to-toll processing on low-cost flexible metal foil or plastic substrates. Substrate materials do not need to tolerate high process temperatures.

These a-CZTS materials are compatible with superstrate or substrate thin-film device configurations, offering flexibility in device architecture and module design. The choice of back-contact metal can be based exclusively on favorable band alignments and material costs, rather than chemical stability during processing. In an a-CZTS device, the back-contact will not be required to survive high-temperature processing in a chalcogen environment. Low-temperature film synthesis offers reduced complexity of deposition equipment and lower energy inputs in manufacturing, further reducing module costs. Because the chemistry of a-CZTS is very different than a-Si:H, these materials might not suffer from light-induced metastabilities such as the Staebler-Wronski Effect (SWE) to the same extent.

There are a number of potential advantages of a-CZTS materials compared to use of amorphous silicon in PV devices such as solar cells, with metastabilities and defect tolerance being two that will be understood by those skilled in the art. A-Si:H PV devices suffer from degradation based on the SWE, in which both photoconductivity and dark conductivity decreases upon exposure to light. Although there are models that attempt to explain the SWE in a-Si:H, it is still not yet fully understood, and, more importantly, no methods have been found to completely eliminate this effect in a-Si:H PV devices. Nevertheless, it is clear that the passivating agent, hydrogen, plays a role.

There have been no experimental studies reported on light-induced metastabilities in a-CZTS materials. Similar metastabilities in a-CZTS might not exist, or, if they exist, they might be of a very different character because methods for passivation in this material system will likely be very different. Metastable effects are known in non-tetrahedral amorphous chalcogenides such as As₂S₃, where prolonged light exposure causes photodarkening, which appears as either a decrease of the bandgap or an increased Urbach edge. However, proposed mechanisms for metastabilities in AChS materials like As₂S₃ are related to the same physics that makes doping difficult in non-tetrahedral amorphous semiconductors. Therefore, tetrahedrally coordinated AChS materials like a-CZTS may be more stable under illumination.

Tetrahedral chalcogenides, such as CIGS, are highly tolerant of native defects, as evidenced by their success in high-efficiency thin-film PV devices. This defect tolerance derives from phenomena that lead to ordered-defect compounds (ODCs), including Cu-poor phases such as CuIn₃Se₅, CuIn₅Se₈, and the like. Stated briefly, the Cu-In—Se system (and related alloys) is highly tolerant of Cu-poor compositions that deviate from the ideal 1:1:2 chalcopyrite stoichiometry because these conditions lead to the formation of ordered arrays of electrically neutral point defect complexes, (In_{Cu}+2V_{Cu}).

ODC phases are believed to play a critical role in CIGS device performance, chiefly through the effects of grain-boundary passivation and the formation of an n-type ODC layer at the CIGS/CdS interface that leads to a more favorable conduction-band alignment. These ODC phases (including surface, bulk and single-crystal forms) have been observed in many experimental studies, and the existence of chalcopyrite ODC phases has been explained through first-principles calculations. In XPS studies on crystalline CZTS phases, Cu-poor surface compositions that pin the Fermi level near midgap in otherwise p-type material have been observed as behavior that is essentially identical to that seen in CIGS materials.

A recent first-principles study finds that Cu₂SnX₃ (X═S,Se) can be described as an ODC of Cu₂ZnSnX₄ via ordering of the defect complex (2Cu_{Zn}+Sn_{Zn}). Similarly, ZnS can be thought of as an ODC of CZTS, by invoking the defect complex (2Zn_{Cu}+Zn_{Zn}). Therefore, even in crystalline CZTS materials, there might be a near-continuum of ODC phases running along the CTS-CZTS—ZnS tie line. All of this implies that a-CZTS materials could inherit a high degree of defect tolerance from crystalline analogs including c-CZTS and c-CIGS.

Several embodiments have been particularly shown and described. It should be understood by those skilled in the art that changes in the form and details may be made to the various embodiments disclosed herein without departing from the spirit and scope of the disclosure and that the various embodiments disclosed herein are not intended to act as limitations on the scope of the claims. Thus, while a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

1. A method of synthesizing a thin film for use as an absorber in a photovoltaic device, comprising:
providing a substrate in a chamber; and
depositing a film of CZTS material on the substrate, the CZTS material comprising copper, zinc, tin, and at least one chalcogen species,
wherein the depositing comprises tuning an optical bandgap of the film with heterovalent alloying.

2. The method of claim 1, wherein the substrate is provided in the chamber free of direct heating.

3. The method of claim 2, wherein the substrate is maintained at a temperature below 150° C. during the depositing of the film.

4. The method of claim 1, wherein the at least one chalcogen species is selected from the group consisting of oxygen, sulfur, selenium, and tellurium.

5. The method of claim 1, wherein the heterovalent alloying comprises controlling deposition rates for the copper and the zinc to define a copper to zinc ratio.

6. The method of claim 5, wherein the optical bandgap is between about 1.0 eV and about 2.75 eV.

7. The method of claim 6, wherein the heterovalent alloying comprises tuning the optical bandgap to a value between 1 eV and 1.5 eV.

8. The method of claim 1, wherein the depositing comprises, concurrently with and independently from the tuning of the optical bandgap of the film with heterovalent alloying, defining n-type and p-type doping of the thin film with ambivalent alloying.

9. The method of claim 8, wherein the ambivalent alloying comprises tuning a stochiometric amount of the copper in the thin film.

10. A method of forming a thin film for use in photovoltaic devices, comprising:
providing a substrate adapted for use as a back contact of a photovoltaic device;
maintaining the temperature of the substrate below about 300° C.; and
synthesizing a thin film comprising copper, zinc, tin, and at least one chalcogen species to provide a ratio of the copper to the tin of about two.

11. The method of claim 10, wherein the synthesizing provides a ratio of the copper, zinc, and tin to the chalcogen species is about 1.

12. The method of claim 10, wherein synthesizing comprises heterovalent alloying to control deposition rates for the copper and the zinc to define a copper to zinc ratio to tune an optical bandgap in the range of about 1.0 to about 2.75 eV.

13. The method of claim 11, wherein the synthesizing comprises adjusting a quantity of the copper in the thin film to control doping in the thin film.

14. The method of claim 10, wherein the thin film is amorphous and nano-crystalline with tetrahedral coordination of anion and cation species.

15. A photovoltaic device, comprising:
a front contact;
a back contact; and
an absorber comprising an amorphous thin film of copper, zinc, tin, and one or more chalcogens, wherein the amorphous thin film has an optical bandgap having a value in the range of about 1.0 to about 2.75 eV.

16. The device of claim 15, wherein the amorphous thin film has tetrahedral coordination of anion and cation species.

17. The device of claim 15, wherein the amorphous thin film has a ratio of the copper to the tin of about two.

18. The device of claim 17, wherein the amorphous thin film has a ratio of the copper, zinc, and tin to the chalcogen species of about 1.

19. The device of claim 15, wherein the chalcogen species comprises sulfur, selenium, or a combination of sulfur and selenium.

20. The device of claim 15, wherein the amorphous thin film is deposited on the back contact while maintaining the back contact at temperatures less than about 300° C.
